(19) United States
(12) Patent Application Publication
(10) Pub. No.: US 2011/0232820 A1
(43) Pub. Date: Sep. 29, 2011

(54) ADHESIVE TAPE JOINING METHOD AND ADHESIVE TAPE JOINING APPARATUS

(76) Inventors: Masayuki Yamamoto, Osaka (JP); Chouhei Okuno, Osaka (JP)

(21) Appl. No.: 13/050,007

(22) Filed: Mar. 17, 2011

(30) Foreign Application Priority Data
Mar. 23, 2010 (JP) 2010-066504

(51) Int. Cl. H05K 3/00; B32B 37/02; B32B 37/12; B32B 37/14

(52) U.S. Cl. 156/60; 156/510; 156/382

(57) ABSTRACT

A frame transport unit places a ring frame on a frame holding section of a holding table, and a holding arm suspendingly holds a protection sheet to place it on a wafer holding table. The holding arm suction-holds a wafer to place it on the protection sheet such that a circuit surface of the wafer is directed downward. An adhesive tape is joined to the wafer and the ring frame suction-held via the protection sheet.

### BACKGROUND OF THE INVENTION

(1) Field of the Invention

The present invention relates to an adhesive tape joining method and apparatus for joining a supporting adhesive tape to a ring frame and an electronic substrate, such as a semiconductor wafer (hereinafter, appropriately referred to as a “wafer”), a printed substrate, and a substrate having chips mounted on a stainless steel plate to hold the electronic substrate on the ring frame.

(2) Description of the Related Art

A wafer as an electronic substrate has a rear surface with a back grinding process subject thereto for obtaining a desired thickness. Here, the wafer is held on the ring frame via a supporting adhesive tape. In such case, the wafer having a protective adhesive tape joined to a surface thereof with a circuit pattern formed thereon is suction-held on a chuck table made of a porous material such as ceramics or a metal, the surface thereof being directed downward. See Japanese Patent Publication No. H10-50642.

However, high-temperature processing such as gold evaporation is recently performed to the rear face of the back-ground wafer. The adhesive tape is an organic material, and is melted through high-temperature processing. Accordingly, the adhesive tape is separated from the wafer surface prior to the high-temperature processing. A new adhesive tape is joined to the wafer surface after the high-temperature processing. Consequently, it is necessary to repeat joining and separating of the adhesive tape, which causes complicated processing. As a result, such disadvantages may arise as an upsized apparatus configuration and a reduced processing speed.

### SUMMARY OF THE INVENTION

This invention has one object to provide a method and apparatus for joining an adhesive tape that allow reduction in size and an enhanced working efficiency of the apparatus.

This invention discloses an adhesive tape joining method for joining a supporting adhesive tape to a ring frame and an electronic substrate to adhesively hold the electronic substrate on the ring frame. The method includes the steps of placing a protection sheet having an identical shape and an equal size to the electronic substrate or more on a surface of a holding table on a middle position of the ring frame by a transport device; placing the electronic substrate on the protection sheet by the transport device with a circuit surface of the electronic substrate directed downward; and joining the adhesive tape to the ring frame and the electronic substrate by a tape joining mechanism.

According to the foregoing method, the protection sheet is interposed between the electronic substrate and the holding table. Consequently, a new protective adhesive tape does not need to be joined to the electronic substrate after heating. Specifically, the protection sheet may achieve suppression of damages in the circuit surface due to rubbing of the electronic substrate and the holding table, or damages in the circuit surface between a joining member and the electronic substrate due to pressure upon joining the adhesive tape to the electronic substrate and the ring frame.

Moreover, the surface-protective adhesive tape does not need to be joined to the surface of the electronic substrate repeatedly, which results in reduced number of processing steps. As a result, reduction in size and an enhanced working efficiency of the apparatus may be realized.

Moreover, the foregoing method may adopt the protection sheet with air permeability or with non-air-permeability. The protection sheet with non-air-permeability may have projections and depressions at given pitches.

With the air-permeable protection sheet, the adhesive tape may be joined to the ring frame and the electronic substrate as follows. That is, the electronic substrate is suction-held on the holding table via the protection sheet. The adhesive tape is joined to the ring frame and the electronic substrate through rolling of a joining roller provided in the tape joining mechanism.

According to this method, the electronic substrate is suction-held on the holding table. Consequently, the electronic substrate does not slide in a rolling direction due to pressure rolling of the joining roller. As a result, damages in the circuit surface may be suppressed occurring from rubbing of the electronic substrate and the holding table.

With the non-air-permeable protection sheet, the adhesive tape may be joined to the ring frame and the electronic substrate as follows. That is, the adhesive tape is joined to the ring frame while a joining roller provided in the tape joining mechanism rolls. Thereafter, the electronic substrate held at least on the holding table is housed into a chamber, and the adhesive tape is joined to the electronic substrate while pressure within the chamber is reduced.

According to this method, only pressure in a vertical direction is applied on the rear surface of the electronic substrate upon joining of the adhesive tape. Consequently, the adhesive tape may be joined accurately without suction-holding the electronic substrate on the holding table. That is, rubbing of the electronic substrate and the holding table may be suppressed that possibly occurs due to rolling of the joining roller.

Moreover, the above method may adopt an inserting paper as the protection sheet between the electronic substrates to be housed in a stack manner. Where the inserting paper is adopted, the inserting paper is removed from the holding table by the transport device after joining of the adhesive tape. Moreover, examples of the electronic substrate in the above method include a semiconductor wafer.

This invention also discloses adhesive tape joining apparatus for joining a supporting adhesive tape to a ring frame and an electronic substrate to adhesively hold the electronic substrate on the ring frame. The apparatus includes a transport mechanism, a holding table, a frame transport mechanism, a frame holder, a tape supply mechanism, a tape joining mechanism, a tape cutting mechanism, and a tape collecting mechanism. The transport mechanism transports a protection sheet and the electronic substrate alternately. The holding table holds a circuit surface of the electronic substrate via the protection sheet already placed by the transport mechanism. The frame transport mechanism transports the ring frame. The frame holder places and holds the ring frame. The tape supply mechanism supplies the adhesive tape toward the ring frame and the electronic substrate. The tape joining mechanism joins the adhesive tape to the ring frame and the electronic substrate. The tape cutting mechanism cuts the adhesive tape along a contour of the ring frame. The tape collecting mechanism collects an unnecessary cut-out adhesive tape.

According to this configuration, the transport mechanism alternately transports the protection sheet and the electronic substrate on the holding table. Consequently, the above method may suitably be performed.

It is more preferable that the foregoing configuration with the air-permeable protection sheet has a further following configuration. That is, an aligner is provided for performing alignment of the protection sheet and the electronic substrate. The holding table suction-holds the electronic substrate via the air-permeable protection sheet. The tape joining mechanism rolls a joining roller to join the adhesive tape to the ring frame and the electronic substrate.

According to this configuration, the electronic substrate is suction-held on the holding table via the protection sheet. In other words, the electronic substrate does not slide in its moving direction due to pressure and movement of the joining member, such as the joining roller, provided in the tape joining mechanism. As a result, damages in the circuit surface may be suppressed occurring from rubbing of the electronic substrate and the holding table.

It is more preferable that the foregoing configuration with the non-air-permeable protection sheet has a further following configuration. That is, an aligner is provided for performing alignment of the protection sheet and the electronic substrate. The joining mechanism includes a joining roller and a chamber. The joining roller joins the adhesive tape to the ring frame. The chamber has a pair of housings. The housing accommodate the holding table for nipping at least the adhesive tape between an outer periphery of the electronic substrate on the holding table and the ring frame to place and hold the electronic substrate, and reducing internal pressure to join the adhesive tape to the electron substrate.

According to this configuration, internal pressure within the chamber is reduced upon joining the adhesive tape, whereby pressure only in the vertical direction is applied to the rear face of the electronic substrate. Consequently, the adhesive tape may accurately be joined to the electronic substrate without suction-holding the electronic substrate on the holding table. That is, rubbing of the electronic substrate and the holding table may be suppressed that possibly occurs due to movement of the joining member.

The transport mechanism in the foregoing configuration may preferably includes a holding arm, a compressor, and a controller. The holding arm holds the electronic substrate and the protection sheet. The compressor is in fluid communication with the holding arm via a channel. The controller performs switching control of the compressor so as to spray compressed air toward the electronic substrate or the protection sheet from a holding surface of the holding arm to generate negative pressure between the holding surface and the electronic substrate or the protection sheet for suspendingly holding the electronic substrate or the protection sheet, or for suction-holding the electronic substrate or the protection sheet with the holding arm for transportation.

According to this configuration, the electronic substrate or the protection sheet may be transported to the holding table with no contact thereof to the holding arm. Moreover, where the electron substrate is an object to be transported in a non-contact manner, warp in the electronic substrate may be corrected that occurs upon suspendingly holding of the electronic substrate. Consequently, the electronic substrate with the warp therein corrected may be transported to the holding table.

Moreover, the holding arm preferably has a through hole formed therein in communication with the channel inside from the holding surface. The through hole includes two or more groups of holes formed at given pitches concentrically and arranged on the holding surface.

According to this configuration, oblique and outward spraying of compressed air to the electronic substrate may achieve efficient generation of negative pressure due to an ejector effect and a Bernoulli effect as well as of positive pressure due to an air-cushion effect. Consequently, the electron substrate may be suspendingly held and transported positively while floating.

Moreover, where the above apparatus adopts the air-permeable protection sheet, the electronic substrate may be suspendingly held and transported positively through spraying of compressed air thereto for floating once.

Additional features of the invention will be preset forth in the description which follows, and in part will be apparent from the description, or may be learned by practice of the invention.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing a configuration of adhesive tape joining apparatus.

FIG. 2 is a front view of the adhesive tape joining apparatus.

FIG. 3 is a side view of a holding table.

FIG. 4 is a longitudinal sectional view of the holding table.

FIG. 5 is a front view partially showing a transport mechanism.

FIG. 6 is a plan view partially showing the transport mechanism

FIG. 7 is a front view of the transport mechanism.

FIG. 8 is a plan view showing a principal portion of the transport mechanism.

FIG. 9 is a plan view showing a principal portion of a holding arm.

FIG. 10 is an enlarged plan view showing a pad of the holding arm.

FIG. 11 is a sectional view on arrow A-A of the pad of the holding arm in FIG. 9.

FIG. 12 is a plan view showing a moving structure of the transport device and a frame transport device.

FIGS. 13 and 14 are front views each partially showing a forward/backward movement structure of the substrate transport device and the frame transport device.

FIG. 15 is a front view of the frame transport device.

FIG. 16 is a plan view of an adhesive tape joining section.

FIG. 17 is a front view of the adhesive tape joining section.

FIGS. 18 through 27 are explanatory views of operations of the adhesive tape joining apparatus.

FIG. 28 is a perspective view of a mount frame.

FIG. 29 is a front view of a tape joining section in one modified apparatus.

FIG. 30 is a side view of the tape joining section.

FIGS. 31 through 35 are explanatory views of operation of the modified apparatus.

### DESCRIPTION OF THE PREFERRED EMBODIMENTS

The invention is described more fully hereinafter with reference to the accompanying drawings, in which embodiments of the invention are shown. This invention may, however, be embodied in many different forms and should not be construed as limited to the embodiments preset forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

One embodiment of the present invention is now described below with reference to the drawings.

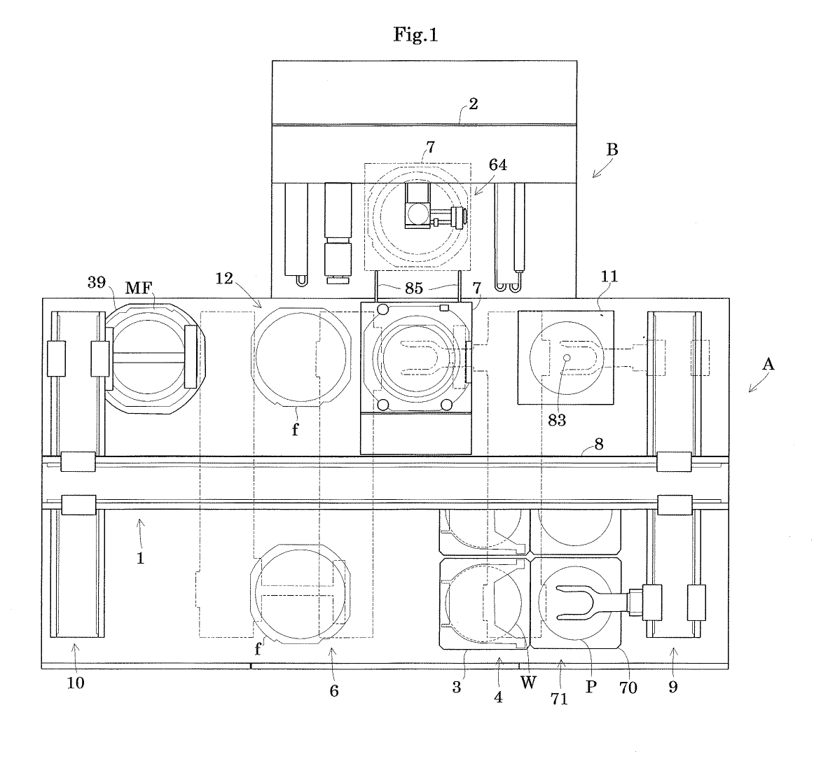

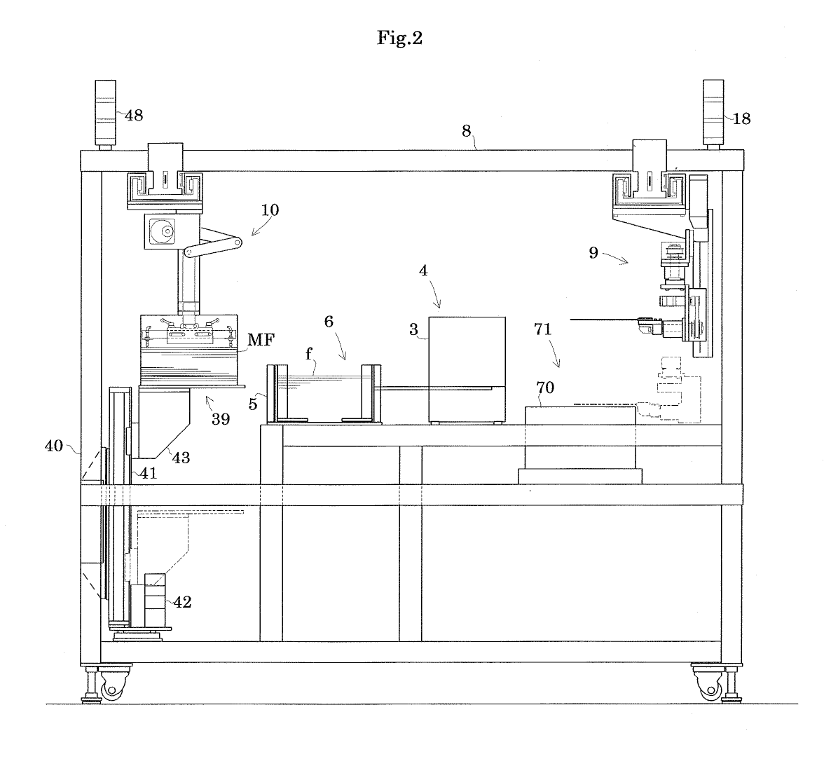

FIG. 1 is a plan view of adhesive tape joining apparatus according to this invention. FIG. 2 is a front view thereof.

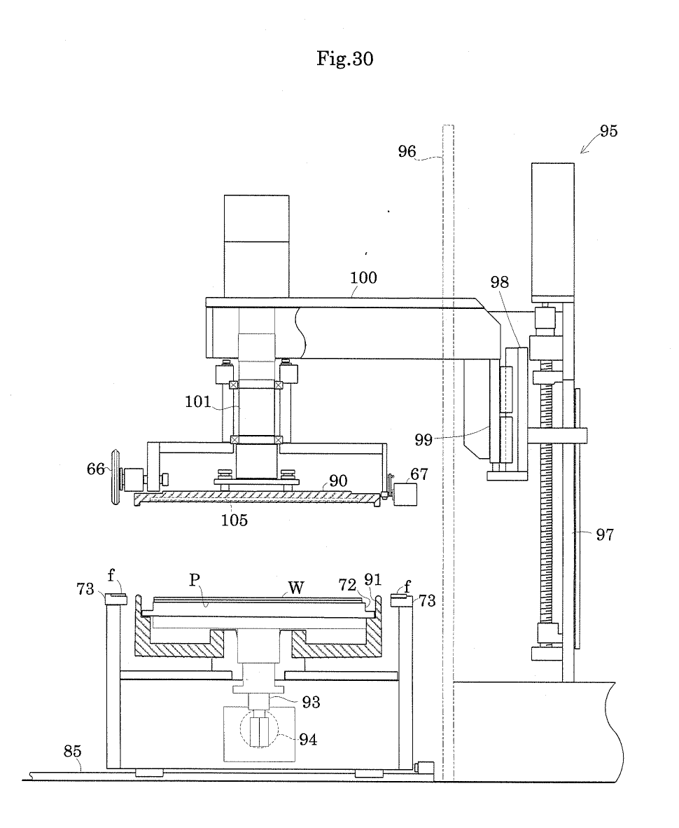

As shown in FIG. 28, the adhesive tape joining apparatus joins an adhesive tape DT to a ring frame f and a semiconductor wafer W (hereinafter, simply referred to as a “wafer W”), which is one example of an electronic substrate, having a circuit pattern formed on a surface thereof exposed for manufacturing a mount frame MF.

As shown in FIG. 1, the adhesive tape joining apparatus includes a laterally-extending rectangular section A and a protrusion section B connected at a center of the rectangular section A so as to protrude rearward from the center. Here, in the following description, a longitudinal direction of the rectangular section A is referred to as a horizontal direction. Moreover, a direction orthogonal to the horizontal direction is referred to as a front side and a back side (upper and lower sides in FIG. 1.)

A transport mechanism 1 is disposed on the rectangular section A. Herein, the transport mechanism 1 transports a wafer W, a ring frame f and a mount frame MF. On the other hand, an adhesive tape joining section 2 is disposed on the protrusion section B. Herein, the adhesive tape joining section 2 joins an adhesive tape DT to a ring frame f and a wafer W for manufacturing a mount frame MF.

As shown in FIGS. 1 and 2, a wafer supply section 4 is disposed on the rectangular section A at a rightward front side with respect to the center of the rectangular section A, and a sheet supply section 71. The wafer supply section 4 houses the wafers W in a cassette 3 in a stack manner for supplying them. The sheet supply section 71 houses surface-protection sheets P in a case 70 in a stack manner for supplying them. In this embodiment, two cassettes 3 and two cases 70 are arranged in parallel.

Moreover, this embodiment adopts one of the cases 70 in the sheet supply section 71 for collecting a used protection sheet P.

Moreover, a frame supply section 6 is disposed on the rectangular section A at a leftward front side with respect to the center of the rectangular section A. The frame supply section 6 includes a case 5 that houses ring frames fin a stack manner for supplying them. Further, a holding table 7 is disposed on the rectangular section A at a rear side near the center of the rectangular section A (near the adhesive tape joining section 2) for transferring a wafer W and a ring frame f each placed thereon to the adhesive tape joining section 2.

Here, the protection sheet P in this embodiment adopts an air-permeable inserting paper. The protection sheet P, however, is not limited to this aspect. For instance, the protection sheet P may be an elastic body having many minute through holes formed therein due to foaming expansion.

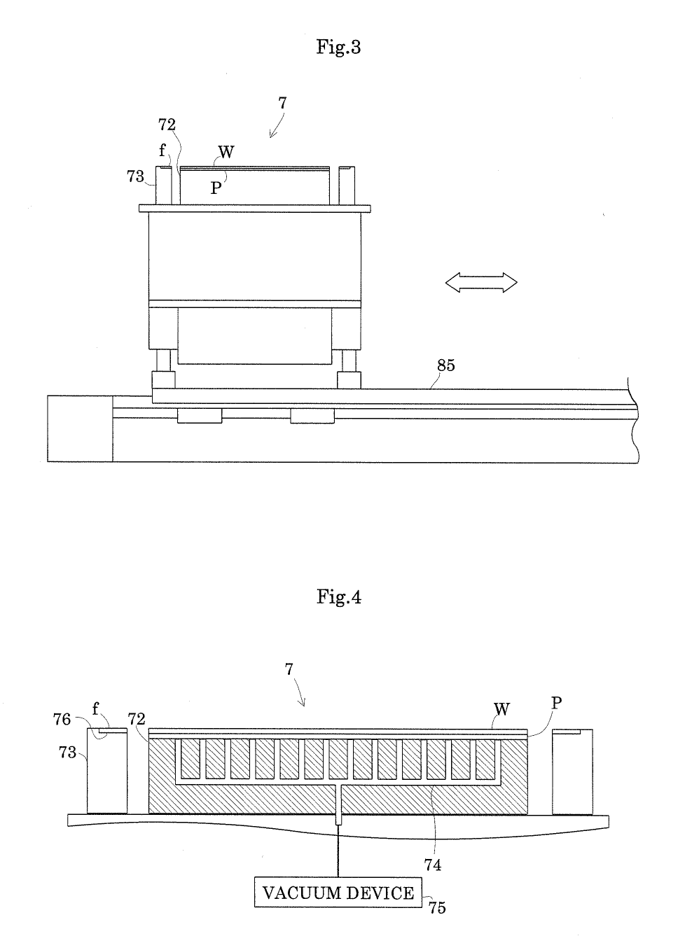

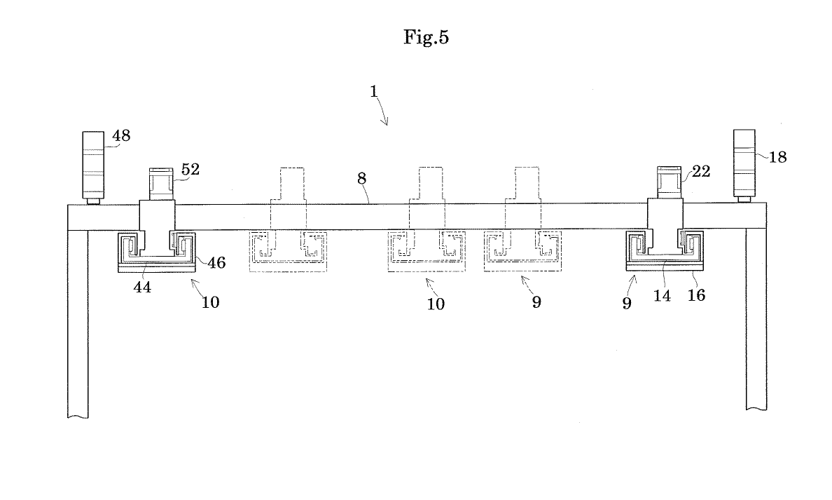

As shown in FIGS. 3 and 4, the holding table 7 has a wafer holding table 72 at a center thereof and a frame holder 73. The wafer holding table 72 places and holds the protection sheet P and the wafer W. The wafer holder 73 surrounds the wafer holding table 72.

The wafer holding table 72 is a metal chuck table. The wafer holding table 72 is in communication with an external vacuum device 75 via a channel 74. The wafer holding table 72 suction-holds the wafer W placed thereon via the protection sheet P. The wafer holding table 72 moves upward and downward with a cylinder 84 (see FIG. 21.) Here, the holding table 72 is not limited to metal, but may be formed of a ceramic porous material.

The frame holder 73 has a step 76 formed therein with an equal thickness to that of the frame. The frame holder 73 is configured such that an upper surface of the ring frame f is equal in level to the top of the frame holder 73 upon placing the ring frame f in the step 76. Moreover, the frame holder 73 is configured such that the surface of the wafer W is equal in level to that of the ring frame f upon placing the protection sheet P and the wafer W on the wafer holding table 73.

As shown in FIGS. 1 and 3, the holding table 7 reciprocates with a drive mechanism along a rail 85 between a set position of the wafer W and the adhesive tape joining section 2.

The transport mechanism 1 includes a transport device 9 and a frame transport device 10. The transport device 9 is supported at a right side of a guide rail 8 so as to reciprocate horizontally. Herein, the guide rail 8 is provided horizontally at an upper side of the rectangular section A so as to extend horizontally. On the other hand, the frame transport device 10 is supported at a left side of the guide rail 8 so as to move horizontally. Moreover, an aligner 11 is provided at a rightward rear side of the rectangular section A. Herein, the aligner 11 performs alignment of the wafer W with a notch or an orientation mark. Further, an aligner 12 is provided at a rear side of the frame supply section 6, and performs alignment of the ring frame f.

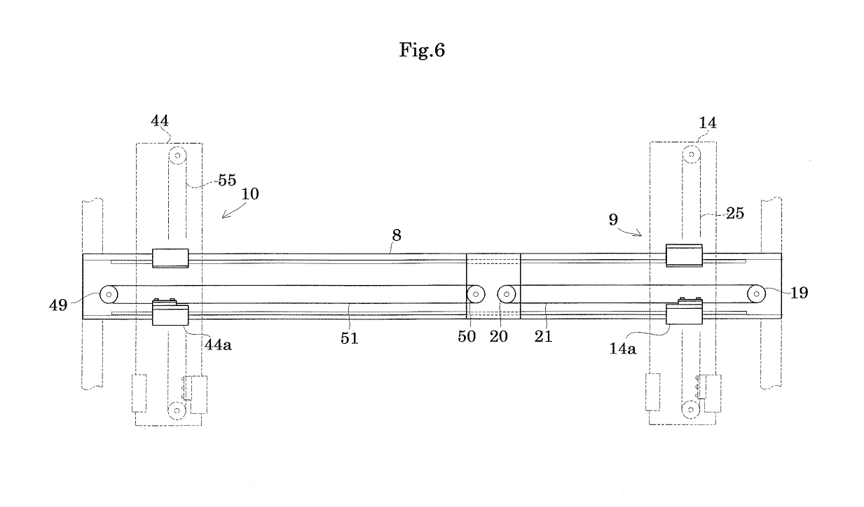

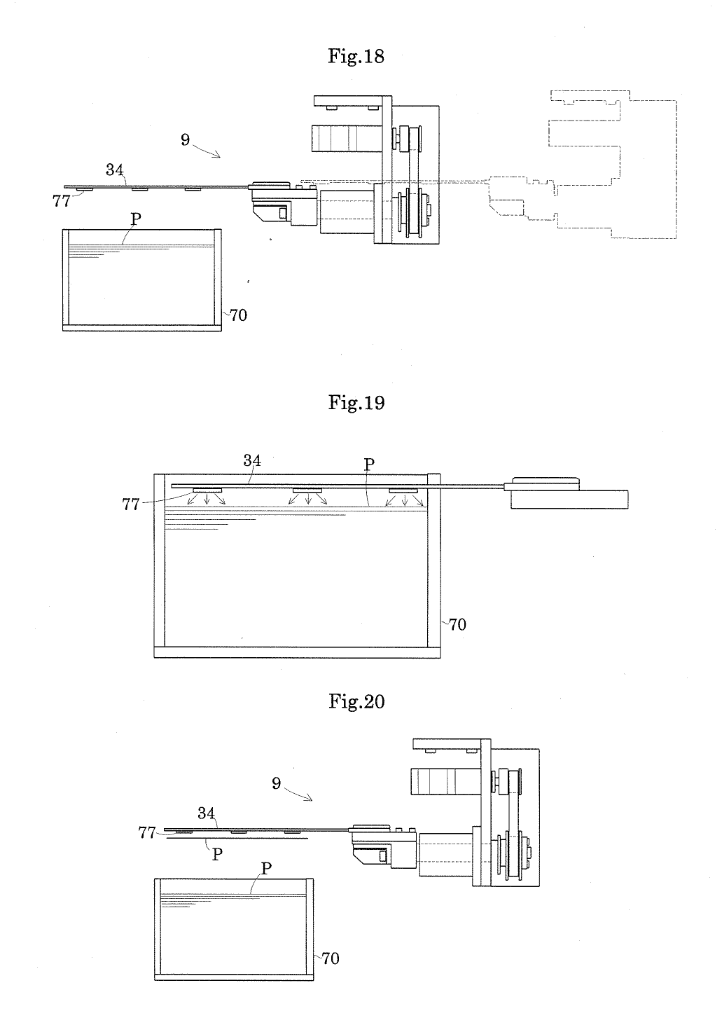

The transport device 9 pulls out a protection sheet P from the case 70 and a wafer W from the cassette 3, and then transports the protection sheet P and the wafer W horizontally and forward/backward. Further, the transport device 9 may turn the wafer W upside down. FIGS. 5 to 14 show a detailed structure of the above.

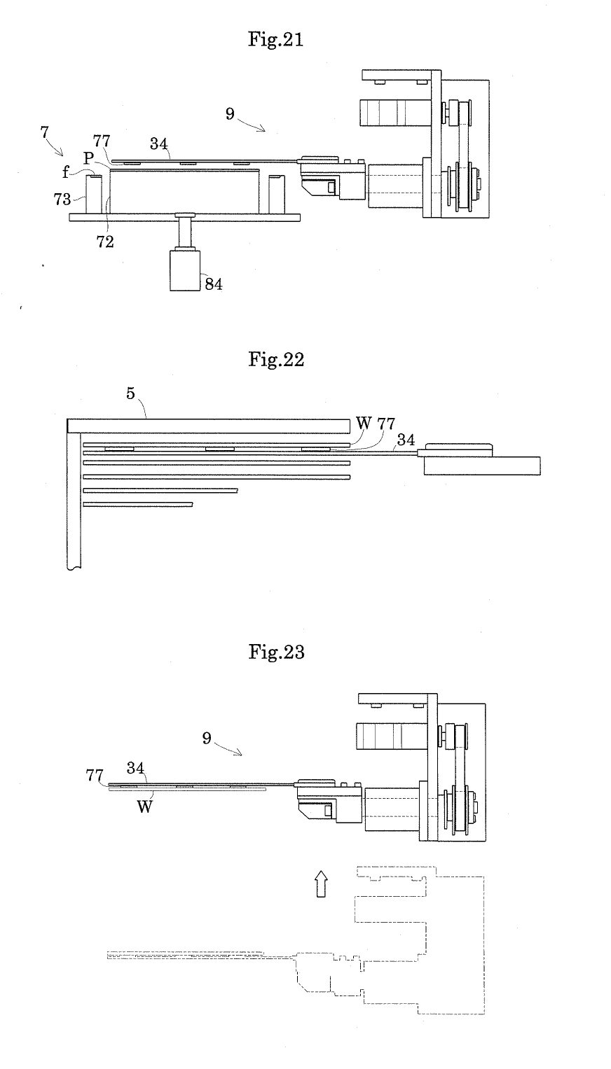

As shown in FIGS. 5 through 7 and 15, the transport device 9 includes a horizontally movable table 14 that moves horizontally along the guide rail 8. The horizontally movable table 14 corresponds to a horizontally movable table 44 in the frame transport device 10. The transport device 9 also includes a forward/backward movable table 16 that moves horizontally along a guide rail 15 provided in the horizontally movable table 14. The forward/backward movable table 16 corresponds to a forward/backward movable table 46 in the frame transport device 10. See FIG. 15. The transport device also includes a holding unit 17 provided below the forward/backward movable table 16 for holding the wafer W and the protection sheet P.

A driving pulley 19 is pivotally supported near a right end of the guide rail 8 and is driven by a motor 18 so as to rotate forward/backward. Moreover, an idling pulley 20 is pivotally supported near a center of the guide rail 8. Further, a belt 21 is wound between the driving pulley 19 and the idling pulley 20, and a slide engagement section 14a in the horizontally movable table 14 is connected to the belt 21. Consequently, the belt 21 rotates forward/backward, and accordingly the horizontally movable table 14 moves horizontally.

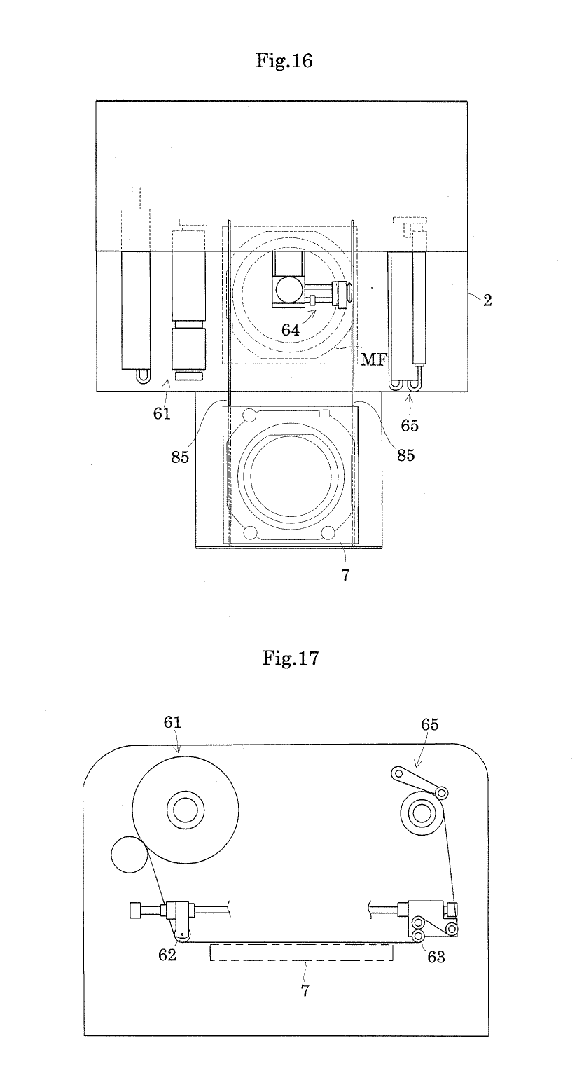

As shown in FIGS. 12 through 14, a driving pulley 23 is pivotally supported adjacent to a rear end of the horizontally movable table 14 and is driven by a motor 22 so as to rotate forward/backward. Moreover, an idling pulley 24 is pivotally supported near a front end of the horizontally movable table 14. Here, the motor 22 corresponds to a motor 52, the driving pulley 23 to a driving pulley 53, and the idling pulley 24 to an idling pulley 54, respectively, in the frame transport device 10. Further, a belt 25 is wound between the driving pulley 23 and the idling pulley 24, and a slide engagement section 16a in the horizontally movable table 16 is connected to the belt 25. Here, the belt 25 corresponds to a belt 55, and the slide engagement section 16a to a slide engagement section 46a, respectively, in the frame transport device 10. The belt 25, 55 rotates forward/backward, and accordingly the horizontally movable table 16 moves horizontally.

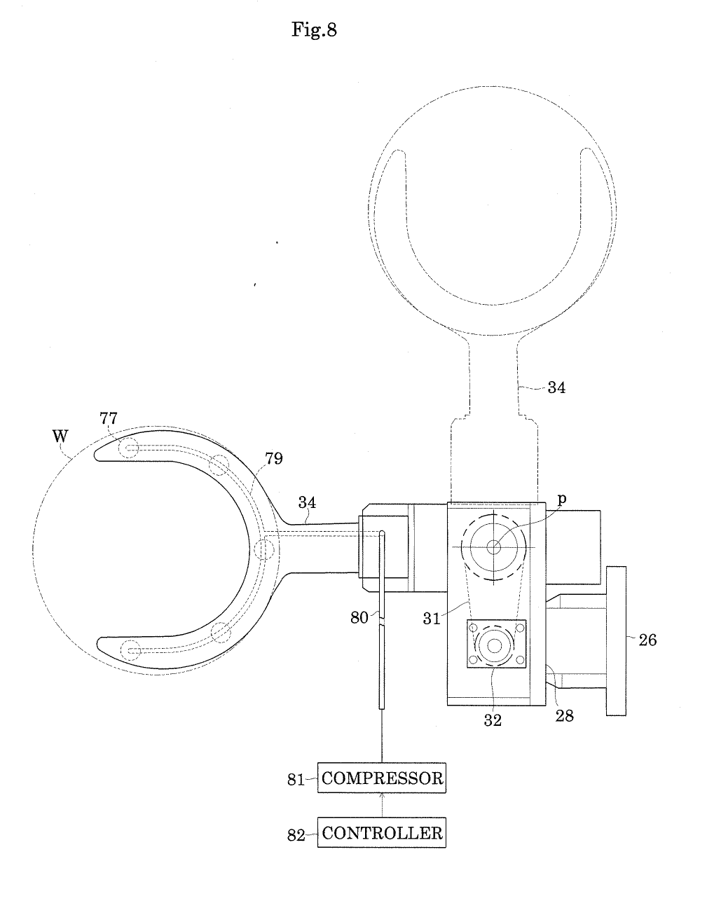

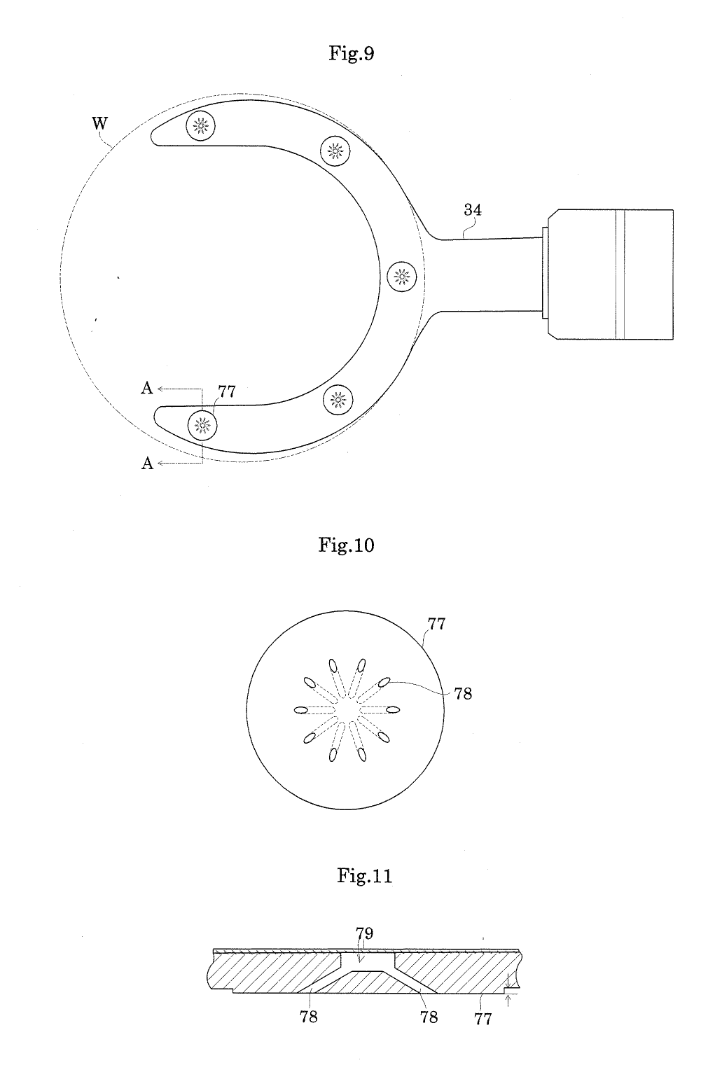

As shown in FIGS. 7 and 8, the holding unit 17 includes an inverted L-shaped support frame 26, a lifting table 28, a turning table 30, a pivoting motor 32, a holding arm 34, and a counter-rotating motor 36. The support frame 26 is connected to a lower surface of the horizontally movable table 16. The lifting table 28 is driven by a motor 27 in a screw feed manner along a vertical frame of the support frame 26. The turning table 30 is pivotably supported via a turning axis 29 for pivoting about a vertically oriented axis p. The pivoting motor 32 is wound around the turning axis 29 via a belt 31 for interlocking with each other. The holding arm 34 is supported on a lower surface of the turning table 30 for counter-rotating about a horizontal axis q. The counter-rotating motor 36 is wound around the turning axis 33 via a belt 35 for interlocking with each other.

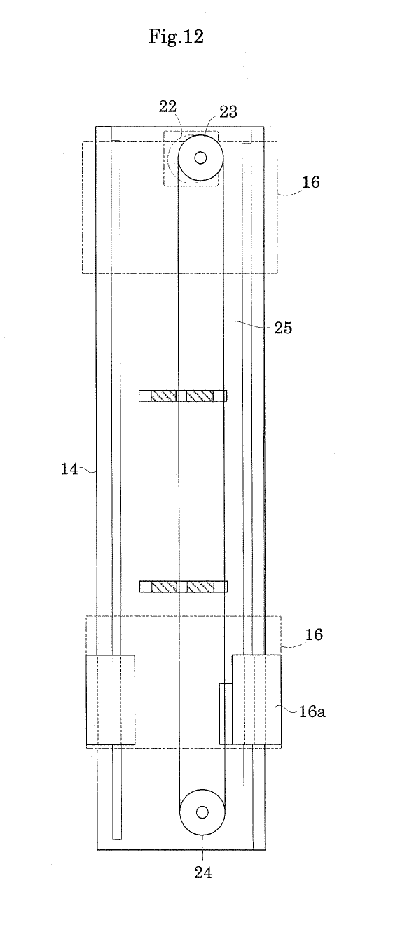

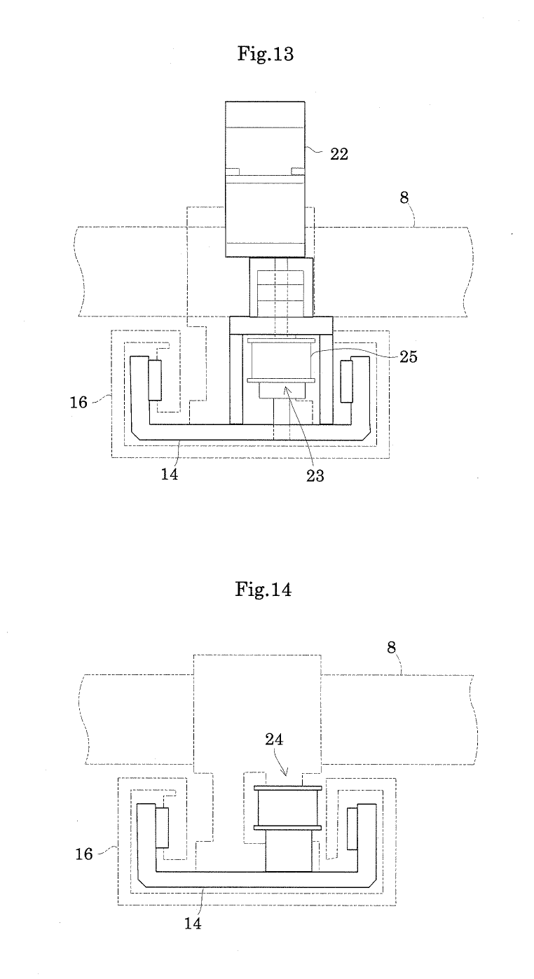

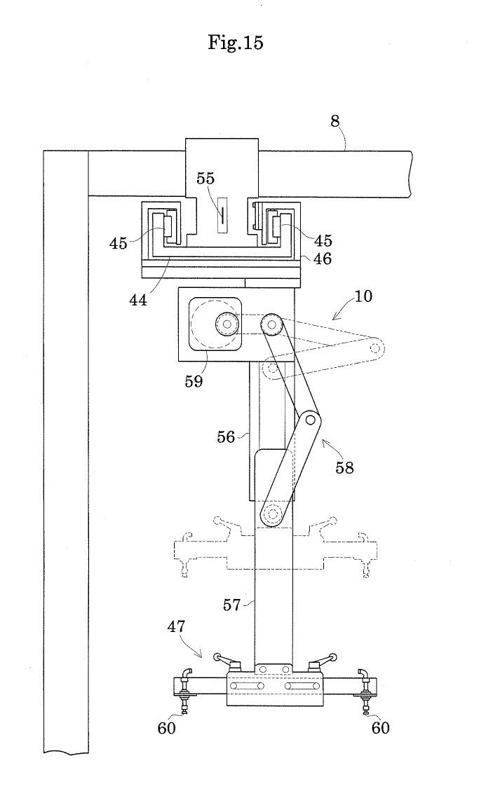

As shown in FIGS. 8 and 9, the holding arm 34 is U-shaped. The holding arm 34 has pads 77 formed on a holding surface thereof that are projected slightly. As shown in FIG. 10, the pad 77 has holes of a small diameter (of approximately 0.2 mm here in this embodiment) inwardly from the surface of the pad 77 that are formed concentrically at given pitches. As shown in FIGS. 8 and 11, the holes 78 are in communication with a channel 79 formed inside the holding arm 34. Each through hole 78 is tapered from the channel 79 inside the holding arm 34 toward the holding surface. The pads 77 are placed in a given position on the holding surface of the holding arm 34. The holding table 34 is in communication with a compressor 81 via the channel 79 formed therein and a connection channel 80 connected to a proximal end of the channel 79.

A controller 82 switches driving of the compressor 81. Specifically, the compressor 81 is driven under negative pressure, whereby the pads 77 of the holding arm 34 suction-holds the rear face of the wafer W. Moreover, the compressor 81 is switched to be driven under positive pressure, whereby the holding arm 34 turns upside down and compressed air is sprayed on the protection sheet P from the holes directed downward. That is, the holding arm 34 may achieve efficient generation of negative pressure between the holding surface thereof and the protection sheet P due to an ejector effect and a Bernoulli effect as well as of positive pressure on the rear face of the protection sheet P due to an air-cushion effect. According to these effects, only an uppermost protection sheet P floats and is held suspendingly by the holding arm 34.

Use of the movable structure described above may achieve the following advantages. That is, the suction-held wafer W may be moved in forward/backward and horizontal directions, and may be turned about the vertically-oriented axis p. As shown in FIG. 7, further, the wafer W may also be turned upside down through the backward rotation about the horizontally-oriented axis q.

Moreover, the protection sheet P may be moved forward/backward and horizontally while being suspendingly held with the holding arm 34.

As shown in FIG. 2, a collection section 39 is disposed at a left side of the frame supply section 6. Herein, the collection section 39 collects to stack mount frames MF manufactured through joining the wafer to the ring frame f via the adhesive tape DT. The collection section 39 includes an upright rail 41 fixedly connected to an apparatus framework 40, and a lifting table 43 driven by a motor 42 so as to move vertically in a screw feed manner along the upright rail 41. Accordingly, the frame supply section 6 allows the mount frame MF to be placed on the lifting table 43 and to move downward in a pitch feed manner.

The frame transport device 10 pulls out an uppermost one of stacked ring frames f from the frame supply section 6 in succession, and then transports each ring frame fin the horizontal and forward/backward directions. The horizontal and forward/backward movement structures of the frame transport device 10 are similar to those of the transport device 9.

As shown in FIGS. 12 and 15, specifically, the frame transport device 10 includes a horizontally movable table 44 that extends and moves horizontally along the guide rail 8. The transport device 10 also includes a forward/backward movable table 46 that moves forward/backward along a guide rail 45 in the horizontally movable table 44. The frame transport device 10 also includes a frame holding unit 47 provided below the forward/backward movable table 46 so as to move vertically.

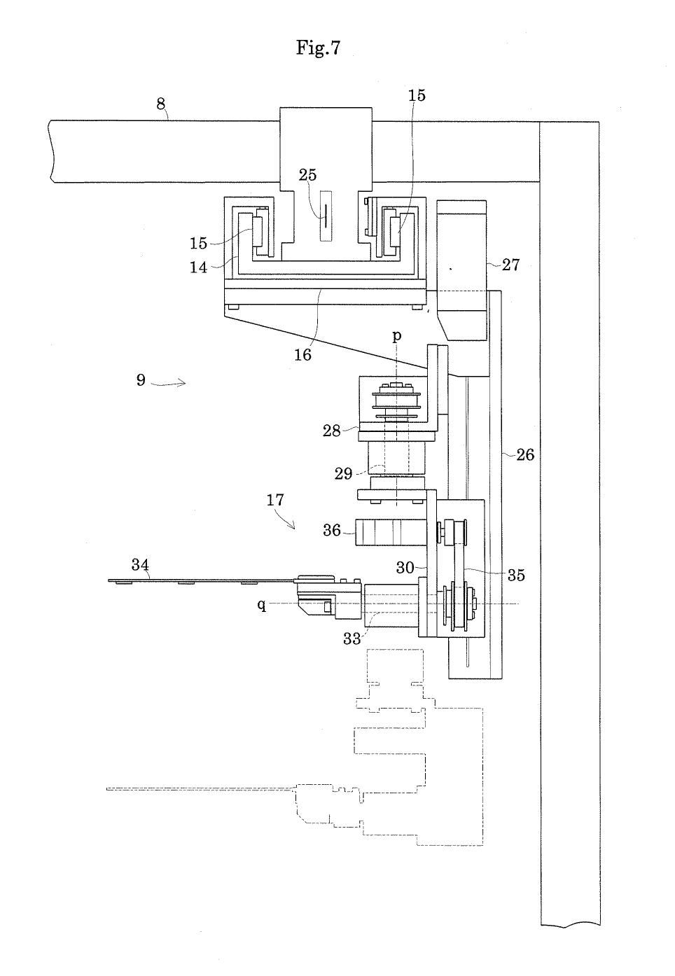

As shown in FIGS. 5 and 6, a driving pulley 49 is pivotally supported near a left end of the guide rail 8 and is driven by a motor 48 so as to rotate forward/backward. Moreover, an idling pulley 50 is pivotally supported near the center of the guide rail 8. Further, a belt 51 is wound between the driving pulley 49 and the idling pulley 50. A slide engagement section 44a in the horizontally movable table 44 is connected to the belt 51. The belt 51 rotates forward/backward, and accordingly the horizontally movable table 44 moves horizontally.

Herein, the configuration shown in FIGS. 12 through 14 for describing the transport device 9 is applied to the description on the frame transport device 10. That is, a driving pulley 53 is pivotally supported near a rear end of the horizontally movable table 44, and is driven by a motor 52 so as to rotate forward/backward. Moreover, an idling pulley 54 is pivotally supported near the rear end of horizontally movable table 44. Further, a belt 55 is wound between the driving pulley 53 and the idling pulley 54. A slide engagement section 46a in the forward/backward movable table 46 is connected to the belt 55. The belt 55 rotates forward/backward, and accordingly the forward/backward movable table 46 moves forward/backward.

As shown in FIG. 15, the frame holding unit 47 includes an upright frame 56 connected to a bottom side of the forward/backward movable table 46, a lifting frame 57 supported so as to slide vertically along the upright frame 56, a bendable link mechanism 58 for moving the lifting frame 57 vertically, a motor 59 for bending the bendable link mechanism 58 forward/backward, and suction pads 60 provided at corners on lower ends of the lifting frame 57. Accordingly, the suction pads 60 suction-hold stacked ring frames fin order from an uppermost one that are stacked on the lifting table 43, and then move upward. Thus, the ring frames f may be transported forward/backward and horizontally. Herein, a position of the suction pad 60 is slidingly adjustable in the horizontal direction in accordance with a size of the ring frame f.

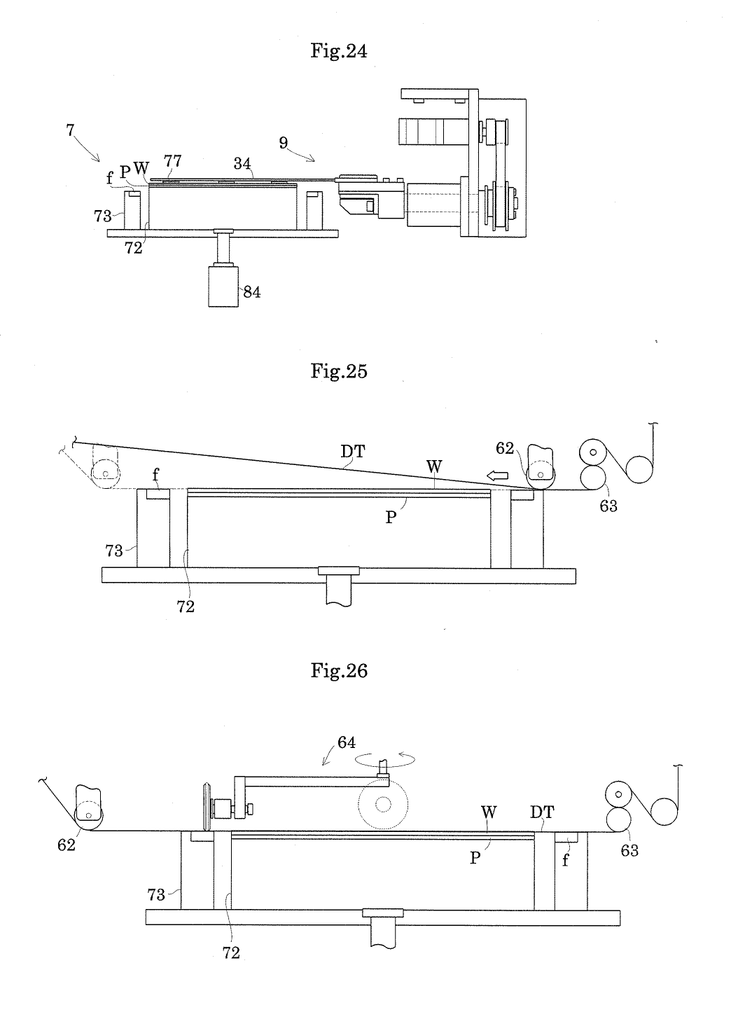

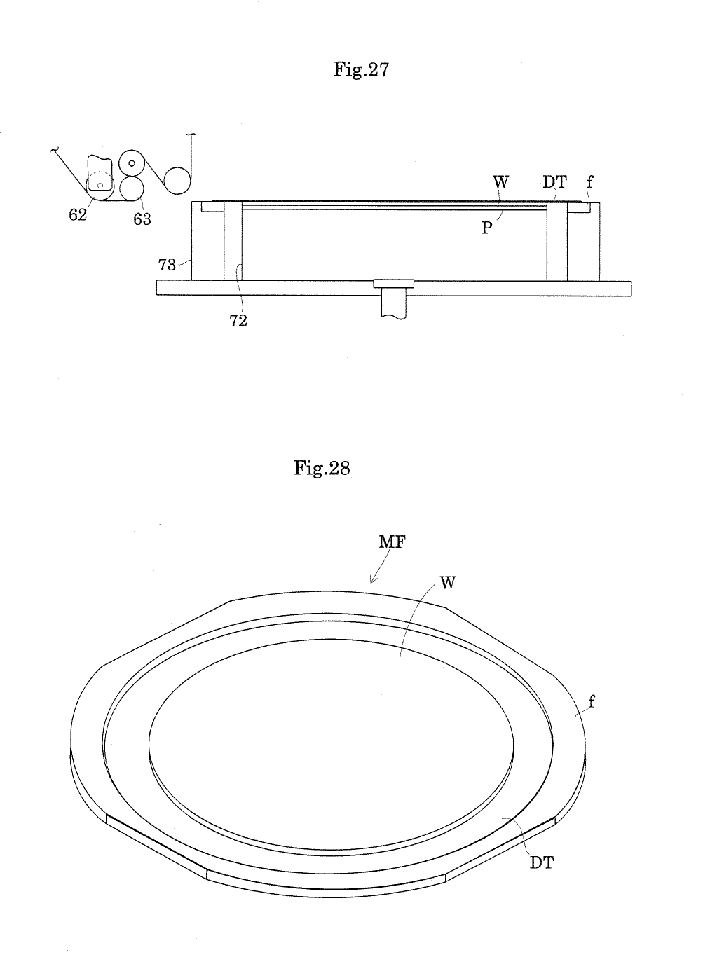

As shown in FIGS. 16 and 17, the adhesive tape joining section 2 includes a tape supply section 61 for housing a wide adhesive tape (a dicing tape) DT in a roll form, a joining roller 62, a separation roller 63, a tape cutting mechanism 64, and a tape collection section 65. That is, when the holding table 7 having the wafer W and the ring frame f placed thereon reaches a tape joining position, the joining roller 62 rolls from right to left in FIG. 17. Thus, the adhesive tape DT is joined onto the wafer W and the ring frame f with rolling of the joining roller 62.

After completion of joining the adhesive tape DT, a disk cutter blade turns with the tape cutting mechanism 28 having moved downward for cutting the adhesive tape DT along the ring frame f. Thereafter, the separation roller 63 rolls from right to left in FIG. 17 to separate an unnecessary portion of the cut adhesive tape DT located outside a cutting line from the ring frame £ Next, the tape collection section 65 winds up and collects a separated unnecessary tape.

Description will be given next of basic operation for joining the adhesive tape DT to the rear face of the wafer W according to the apparatus in the foregoing exemplary embodiment.

First, the frame holding unit 47 in the frame transport device 10 suction-holds the ring frame f from the frame supply unit 6, and places it on the aligner 12. The frame holding unit 47 releases its suction-holding of the ring frame f and moves upward. Then, the aligner 12 performs alignment of the ring frame f. Thereafter, the frame holding unit 47 again suction-holds the ring frame f for transporting it onto the holding table 7, and places the wafer W on the frame holder 73.

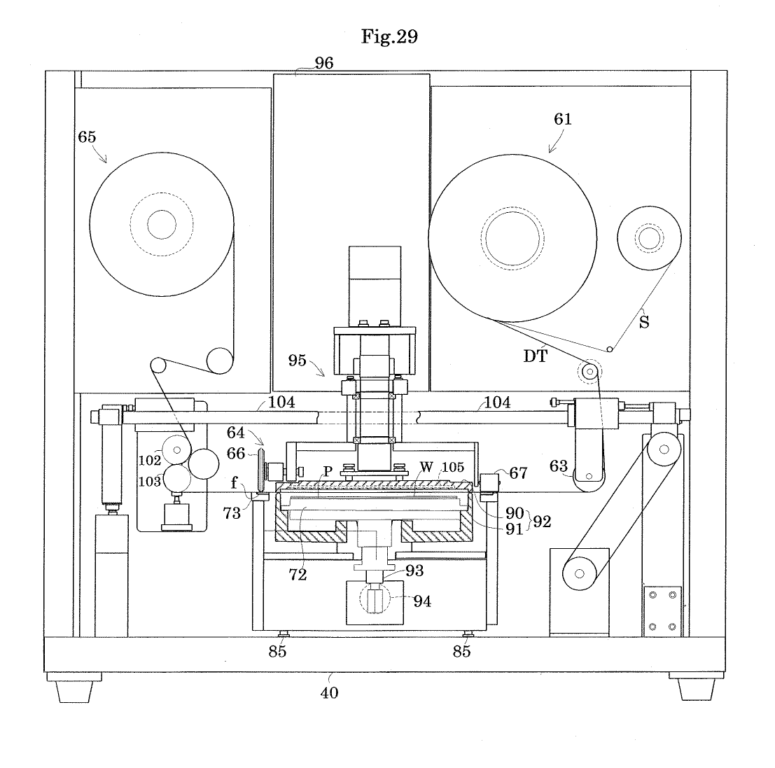

As shown in FIG. 18, the holding arm 34 moves upward above the case 70 in the sheet supply unit 71 while the pads 77 are directed downward. As shown in FIG. 19, the holding arm 34 moves downward into a given level for approaching the uppermost protection sheet P. The compressor 81 is driven under positive pressure in this state for spraying compressed air onto the protection sheet P from the pads 77 in the holding arm 34. Then, airflow smoothly flowing radially on the surface of protection sheet P generates a region of steady negative pressure between the holding surface and the protection sheet P, which results in float of the protection sheet P.

As shown in FIG. 20, the floating protection sheet P is moved above the holding table 7 while being suspendingly held with the holding arm 34. As shown in FIG. 21, the wafer holding table 72 has already moved upward to a position where the surface thereof is higher than the surface of the frame holder 73. The holding arm 34 moves downward to a level where the protection sheet P is brought into contact with the wafer holding table 72. The compressor 81 stops driving to place the protection sheet P on the wafer holding table 72. The protection sheet P on the wafer holding table 72 is aligned with an alignment pin, etc.

The transport device 9 transports the protection sheet P and returns to the wafer supply section 4. Subsequently, the transport device 9 turns the pads 77 in the holding arm 34 upside down so that they are directed upward. As shown in FIG. 22, the holding arm 34 moves forward/backward in this state between the wafers W housed in a stack manner in the cassette 5 of the wafer supply section 4 for contacting the pads 77 to the rear face of the wafer W. There, the wafers W having the circuit surface of the wafer W are directed upward. Upon contacting of the pads 77 to the rear face of the wafer W, the compressor 81 is driven under negative pressure to pull out the wafer W through suction-holding of the rear face of the wafer W. The wafer W is transported above the aligner 11 while being suction-held with the holding arm 34.

The aligner 11 suction-holds the rear face of the wafer W at a center thereof with a suction pad 83 (see FIG. 1) projected from a center of the aligner 11. Simultaneously, the holding arm 34 releases suction-holding of the wafer W and retracts. The suction pad 83 is housed within the table and the aligner 11 performs alignment of the wafer W based on a notch, etc., of the wafer W. Upon completion of the alignment, the suction pad 83 suction-holding the wafer W is projected from a surface of the aligner 11, where the holding arm 34 moves to suction-hold the rear face of the wafer W. Thereafter, the pad 83 releases its suction and moves downward.

As shown in FIG. 23, the holding arm 34 moves upward into a given level while suction-holds the rear face of the wafer W. Then, the holding arm 34 turns upside down such that the circuit surface of the wafer W is directed downward. Thereafter, as shown in FIG. 24, the holding arm 34 moves above the holding table 7 to place the wafer W on the protection sheet P on the wafer holding table 72 while the circuit surface of the wafer W is directed downward. The wafer holding table 72 suction-holds the wafer W placed thereon via the protection sheet P.

Upon completion of setting the wafer W and the ring frame f on the holding table 7, the wafer holding table 72 moves downward. The upper surface of the wafer W is equal in level to that of the ring frame f. Thereafter, the holding table 7 moves to the adhesive tape joining section 2 along the rail 85.

When the holding table 7 reaches a transport position of the tape joining section 2, the joining roller 62 moves downward to roll on the adhesive tape DT from right to left in plane as shown in FIG. 25. Consequently, the adhesive tape DT is joined to the ring frame f and the rear face of the wafer W. When the joining roller 62 reaches its termination position, the tape cutting mechanism 64 moves downward to cut the adhesive tape DT along the ring frame f while turning the cutter blade, as shown in FIG. 26.

Upon completion of cutting the adhesive tape DT, the tape cutting mechanism 64 moves upward, and the separation roller 63 moves from right to left as shown in FIG. 27, thereby winding up and collecting an unnecessary tape after cut out.

Upon completion of manufacturing the mount frame MF as shown in FIG. 28, the holding table 7 moves to a setting position of the rectangular section. A in FIG. 1, and then stops. Here, the frame holding unit 47 suction-holds and transports a manufactured mount frame MF for collecting it into the collection section 39. Moreover, the transport mechanism 9 moves to the holding table 7. The holding arm 34 suspendingly holds the used protection sheet P, and transports the protection sheet P to the collecting case 70 in the sheet supply section 71 in the above state.

Thus, a round of basic operation is completed as mentioned above. The similar operation is to be repeated hereinafter.

The apparatus in the foregoing exemplary embodiment joins the adhesive tape DT to the ring frame f and the wafer W for manufacturing the mount frame MF without joining a new protective tape to a wafer W having a rear face subject to high-temperature processing such as gold evaporation after separating the protective tape joined to the surface of the wafer in a back grinding process. That is, the adhesive tape DT may be joined to the wafer W through interposing the protection sheet P between the wafer holding table 72 and the wafer W with the circuit surface of the wafer W being protected, although the circuit surface of the wafer is exposed.

Consequently, the protective tape does not need to be joined again after high-temperature processing to the wafer W. As a result, joining of a new protective tape and a separation step may be omitted for realizing reduction in size of the apparatus and processing time.

According to this apparatus, the transport mechanism 9 may transport the air-permeable protection sheet P in a non-contact manner. Moreover, the transport mechanism 9 may suction-hold and transport the non-air-permeable wafer W. In addition, with the air-permeable protection sheet P, the transport mechanism 9 may suction-hold and transport the wafer W on the wafer holding table 72 via the protection sheet P. As a result, the wafer W does not slide in the rolling direction through rolling of the joining roller 62, which results in prevention of damages in the circuit surface of the wafer W.

This invention may be embodied as the following aspects.

In the apparatus in the foregoing exemplary embodiment, the air-permeable inserting sheet is adopted as the protection sheet P. The non-air-permeable protection sheet may be adopted. Examples of the protection sheet P include an elastic silicon sheet and a protection sheet having uneven steps formed thereon in a two-dimensional array at given pitches.

Where the non-air permeable protection sheet is interposed between the wafer holding table 72 and the wafer W, only the wafer holding table 72 is housed at least into the chamber. For instance, the adhesive tape joining section 2 is configured so as to join the adhesive tape DT to the wafer W under reduced pressure.

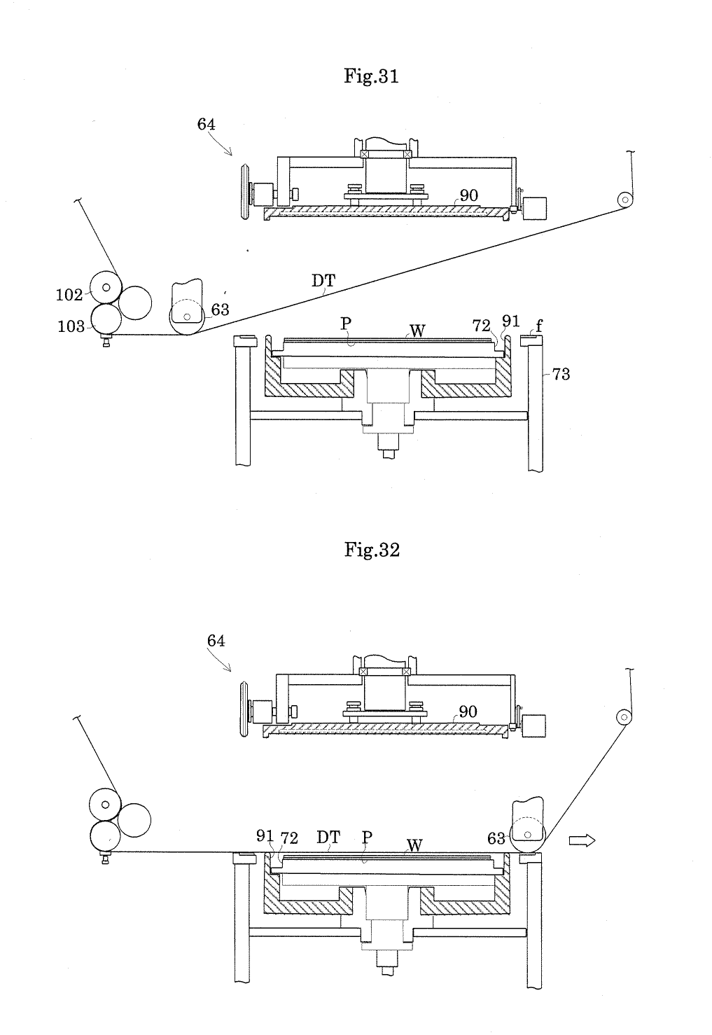

Specifically, as shown in FIG. 29, the holding table 7 has the wafer holding table 72 and the frame holder 73. The wafer holding table 72 holds the wafer W. Furthermore, a lower housing 91 is provided between the wafer holding table 72 and the frame holder 73. The lower housing 91 is integrated with the upper housing 90 in the adhesive tape joining section 2 to form a chamber 92.

The wafer holding table 72 is connected to a rod 93 passing through the lower housing 91 that forms the chamber 92. The rod 93 has the other end drivingly connected to a motor 94. Consequently, the wafer holding table 72 moves upward and downward within the lower housing 91 through forward/backward driving of the motor 94.

A cylindrical upper portion of the lower housing 91 is round and subject to a releasing treatment such as fluorine processing.

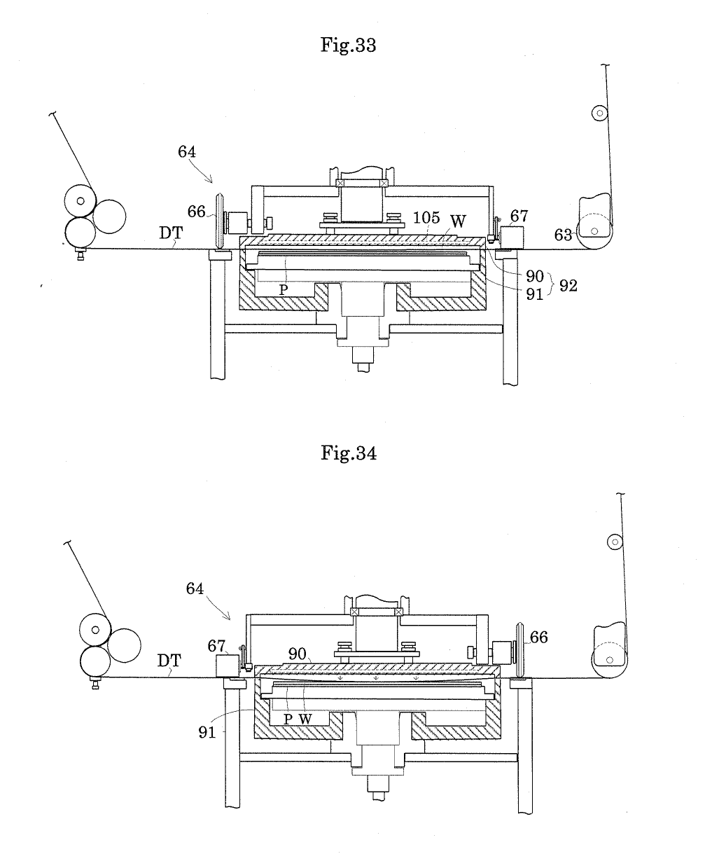

The upper housing 90 is provided in a lifting drive mechanism 95, as shown in FIG. 30. The lifting drive mechanism 95 has a movable table 98, a movable frame 99, and an arm 100. The movable table 98 moves upward and downward along a rail 97 arranged vertically at a backside of a wall 96. The movable frame 99 is supported on the movable table 98 so as to control a level thereof. The arm 100 extends forward from the movable frame 99. The arm 100 includes an axis 101 extending downward from a tip end thereof and having the upper housing mounted thereon.

The chamber 92 formed of a pair of upper and lower housings 90, 91 has a smaller diameter than the width of the adhesive tape DT. That is, both housings 90, 91 nip the adhesive tape DT exposed between the outer periphery of the wafer W and the inner diameter of the ring frame f.

Description will be given next of a round of operation for joining the adhesive tape DT to the ring frame f and the wafer W according to the apparatus in the foregoing exemplary embodiment.

The same operation as that in the above the foregoing exemplary embodiment is performed for transporting and placing the protection sheet P on the wafer holding table 72 in a non-contact manner with the holding arm 34. Thereafter, the wafer W is aligned with the aligner 11 and is transported with the holding arm 34 for placing it on the wafer holding table 72. Here, the holding surface of the wafer holding table 72 is higher than the top of the lower housing 91. Upon placing the wafer W on the wafer holding table 72, the wafer W on the wafer holding table 72 has a surface level slightly lower than the top of the lower housing 91.

Simultaneously, the frame holding unit 47 places the ring frame f aligned with the aligner 12 on the frame holder 73.

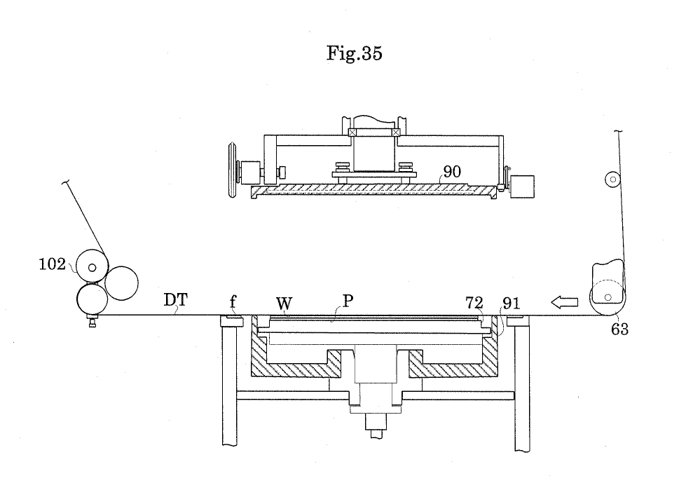

The protection sheet P, the wafer W, and the ring frame f are aligned with the alignment pin, and thereafter the holding table 7 moves into a joining position of the adhesive tape joining section 2. Here, the joining roller 63 is in a standby position on the tape collection section 65 side, as shown in FIG. 31. Moreover, a pinch roller 102 moves downward to nip the adhesive tape DT with a feeding roller 103.

As shown in FIG. 32, the joining roller 63 joins the adhesive tape DT to the ring frame f while rolling to the right along a guide rail 104. The adhesive tape DT is fed out by a given amount from the tape supply section 61 in accordance with rolling of the joining roller 63 while a separator S is separated from the adhesive tape DT.

Upon completion of joining the adhesive tape DT to the ring frame f, the upper housing 90 moves downward, as shown in FIG. 33. With the downward movement, the upper and lower housings 90, 91 nip the adhesive surface of the adhesive tape DT exposed between the outer periphery of the wafer and the inner diameter of the ring frame f, thereby forming the chamber 92. Here, the adhesive tape DT has a function as a seal material, and divides a space within the chamber 92 into an upper housing 90 side and a lower housing 91 side to form two spaces.

The wafer W in the lower housing 91 has a given clearance with respect to the adhesive tape DT.

The controller operates a heater 105 for heating the adhesive tape DT from the upper housing 90 side. Simultaneously, in the channel where the upper housing 90 and lower housing 91 are in communication with the vacuum device via an electromagnetic valve, pressure in both housings 90, 91 are reduced through controlling open and close of the electromagnetic valve. That is, the degree of opening of the electromagnetic valve is controlled such that pressure in both housings 90, 91 are reduced by an equal speed.

Upon reducing of the pressure in both housing 90 and 91 to a given air pressure, the electromagnetic valve closes and the vacuum devices stops its operation.

The controller increases the pressure within the upper housing 90 to a given air pressure while controlling the degree of opening of the electromagnetic valve for leakage. Here, the lower housing 91 has lower air pressure than the upper housing 90. As shown in FIG. 34, pressure difference therebetween leads to drawing of the adhesive tape DT from the center thereof into the lower housing 91. Consequently, the adhesive tape DT is joined gradually from the center towards the outer periphery of the wafer W.

The pressure within the upper housing 90 reaches a preset air pressure, and then the controller controls the degree of opening of the electromagnetic valve for setting the air pressure within the lower housing 91 to be equal to that within the upper housing 90. The wafer holding table 72 moves upward in accordance with the control of the air pressure such that the surface of the ring frame f is equal in level to the upper surface of the wafer W. Thereafter, as shown in FIG. 35, the controller moves the upper housing 90 upward for air release in the upper housing 90. Moreover, the controller completely opens the electromagnetic valve for air release in the lower housing 91.

The tape cutting mechanism 64 operates during joining of the adhesive tape DT to the wafer W within the chamber 92. Here, a cutter 66 in the cutting mechanism 64 cuts the adhesive tape DT along a contour of the ring frame f. Simultaneously, a pressing roller 67 follows the cutter 66 to roll on and press the cutting portion of the adhesive tape DT on the ring frame f. In other words, where the upper housing 90 moves downward to form the chamber 92 with the lower housing 91, the cutter 66 in the tape cutting mechanism 64 and the pressure roller 67 also reach the cutting position, as shown in FIG. 34.

As shown in FIG. 35, joining of the adhesive tape DT to the wafer W and cutting of the adhesive tape DT is completed at the time where the upper housing 90 moves upward. Accordingly, the pinch roller 102 moves upward for releasing nipping of the adhesive tape DT. Thereafter, the joining roller 63 moves into an initial position on the tape collection section 65 side. A cut-out unnecessary adhesive tape DT is wound and collected to the tape collecting section 65 while the adhesive tape DT is fed out by a given amount from the tape supply unit 61.

The joining roller 63 returns to its initial position to manufacture the mount frame MF as shown in FIG. 28. The holding table 7 returns to its setting position. Thereafter, the frame transport unit 47 transports the mount frame MF for collecting it into the collection section 39. Then, the holding arm 34 of the transport mechanism 9 suspendingly holds the protection sheet P for disposal into the collecting case. Thus, a round of operation is completed as mentioned above. The similar operation is to be repeated hereinafter.

The holding arm 34 in the above exemplary embodiment may be configured annularly having tip ends of a U-shape arm coupled to each other, and may have holes formed at given pitches.

The holding arm 34 in the above exemplary embodiment has an aspect of suction-holding the wafer W for transporting the protection sheet P in a non-contact manner. The holding arm 34 may has an aspect of transporting the wafer W in a non-contact manner. In this aspect, the holding arm 34 suspendingly holds and transports the protection sheet P and the wafer W, in this order, from the case 70 in which the wafers W with the circuit surface thereof being directed downward are housed in a stack manner having the protection sheets P interposed therebetween.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An adhesive tape joining method for joining a supporting adhesive tape to a ring frame and an electronic substrate to adhesively hold the electronic substrate on the ring frame, comprising the steps of:
placing a protection sheet having an identical shape and an equal size to the electronic substrate or more on a surface of a holding table on a middle position of the ring frame by a transport device;
placing the electronic substrate on the protection sheet by the transport device with a circuit surface of the electronic substrate directed downward; and
joining the adhesive tape to the ring frame and the electronic substrate by a tape joining mechanism.

2. The adhesive tape joining method according to claim 1, wherein
the protection sheet is air-permeable, and the electronic substrate is suction-held on the holding table via the protection sheet; and
the adhesive tape is joined to the ring frame and the electronic substrate through rolling of a joining roller provided in the tape joining mechanism.

3. The adhesive tape joining method according to claim 1, wherein
the protection sheet is non-air-permeable, the adhesive tape is joined to the ring frame while a joining roller provided in the tape joining mechanism rolls, and thereafter, the electronic substrate held at least on the holding table is housed into a chamber, and the adhesive tape is joined to the electronic substrate while pressure within the chamber is reduced.

4. The adhesive tape joining method according to claim 3, wherein
the protection sheet has projections and depressions at given pitches.

5. The adhesive tape joining method according to claim 1, wherein
the protection sheet is an inserting paper interposed between the electronic substrates to be housed in a stack manner, and
the inserting paper is removed from the holding table by the transport device after joining of the adhesive tape.

6. The adhesive tape joining method according to claim 1, wherein
the electronic substrate is a semiconductor wafer.

7. Adhesive tape joining apparatus for joining a supporting adhesive tape to a ring frame and an electronic substrate to adhesively hold the electronic substrate on the ring frame, comprising:
a transport mechanism for transporting a protection sheet and the electronic substrate alternately;
a holding table for holding a circuit surface of the electronic substrate via the protection sheet already placed by the transport mechanism;
a frame transport mechanism for transporting the ring frame;
a frame holder for placing and holding the ring frame;
a tape supply mechanism for supplying the adhesive tape toward the ring frame and the electronic substrate;
a tape joining mechanism for joining the adhesive tape to the ring frame and the electronic substrate;
a tape cutting mechanism for cutting the adhesive tape along a contour of the ring frame; and
a tape collecting mechanism for collecting an unnecessary cut-out adhesive tape.

8. The adhesive tape joining apparatus according to claim 7, further comprising:
an aligner for performing alignment of an air-permeable protection sheet and the electronic substrate, wherein
the holding table suction-holds the electronic substrate via the air-permeable protection sheet, and
the tape joining mechanism rolls a joining roller to join the adhesive tape to the ring frame and the electronic substrate.

9. The adhesive tape joining apparatus according to claim 7, further comprising:
an aligner for performing alignment of the protection sheet and the electronic substrate, wherein
the joining mechanism is formed of a joining roller for joining the adhesive tape to the ring frame, and a chamber comprising a pair of housings for accommodating the holding table for nipping at least the adhesive tape between an outer periphery of the electronic substrate on the holding table and the ring frame to place and hold the electronic substrate, and reducing internal pressure to join the adhesive tape to the electron substrate.

10. The adhesive tape joining apparatus according to claim 7, further comprising:
a holding arm for holding the electronic substrate and the protection sheet;
a compressor in fluid communication with the holding arm via a channel; and
a controller for performing switching control of the compressor so as to spray compressed air toward the electronic substrate or the protection sheet from a holding surface of the holding arm to generate negative pressure between the holding surface and the electronic substrate or the protection sheet for suspendingly holding the electronic substrate or the protection sheet, or for suction-holding the electronic substrate or the protection sheet with the holding arm for transportation.

11. The adhesive tape joining apparatus according to claim 10, wherein
the holding arm has a through hole formed therein in communication with the channel inside from the holding surface, and
the through hole has groups of holes formed at given pitches concentrically and arranged on the holding surface.

12. The adhesive tape joining apparatus according to claim 10, wherein
the through hole is tapered from the channel inside the holding arm toward the holding surface.
